(19) United States
(12) Patent Application Publication
(10) Pub. No.: US 2009/0243602 A1
(43) Pub. Date: Oct. 1, 2009

(54) METHOD AND APPARATUS FOR TESTING CHARACTERISTIC OF MAGNETIC HEAD

(75) Inventors: Masanori Yaguchi, Kawasaki (JP); Mutsuo Yoshinami, Kawasaki (JP); WooSuk Song, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/236,361

(22) Filed: Sep. 23, 2008

(30) Foreign Application Priority Data
Mar. 25, 2008 (JP) 2008-077286

(51) Int. Cl. G01R 33/12; G11B 5/127

(52) U.S. Cl. 324/210; 29/603.09

(57) ABSTRACT

The method for testing a characteristic of a magnetic head is performed in the form of a wafer, especially in a heating state and a cooling state. The method for testing a characteristic of a magnetic head, in which a wafer including a dummy read-element having a size equal to that of a completed read-element, a product read-element and a heat conductive section being provided in the vicinity of the dummy read-element is tested as a test sample, comprises the steps of: applying an external magnetic field to the test sample; bringing a heat conducting member into contact with the heat conductive section so as to heat or cool the dummy read-element via the heat conductive section; and testing an electromagnetic conversion characteristic of the dummy read-element in a heating state or a cooling state.

### BACKGROUND OF THE INVENTION

The present invention relates to a method and an apparatus for testing a characteristic of a magnetic head, more precisely relates to a method and an apparatus for testing a characteristic of a magnetic head, in which a characteristic of a read-element is tested in the form of a wafer.

In a process of producing magnetic head, an electromagnetic conversion characteristic of a read-element of a magnetic head is tested. By testing the characteristic of the read-element during the production process, no bad elements are inefficiently processed in the following production steps, and the results of the test can be fed back to the prior production step so as to prevent product failure from occurring.

Testing the electromagnetic conversion characteristic of the read-element is mostly performed in the form of a head gimbal assembly (HGA), in which a slider is mounted on a head suspension, or in the form of a raw bar, which is cut from a wafer and in which sliders are laid out in a line. By testing the characteristic of the read-element in these forms, a size of the read-element in a height direction can be firstly defined in the form of the slider or the raw bar, and the characteristic of the read-element can be accurately evaluated.

However, in case of testing the read-element in the form of the raw bar or the HGA, the test is performed in a nearly completed magnetic head, so the results of the test cannot be fed back to the early production step.

To solve the problem, a method of testing the characteristic of a read-element in the form of a wafer has been studied. Conventional methods are disclosed in, for example, Japanese Laid-open Patent Publication Nos. 10-222818, 2001-14622 and 1-201816.

In case of testing the electromagnetic conversion characteristic of a read-element in the form of a wafer in which the read-element has been formed, a size of the read-element in the height direction is not defined, so the characteristic of the read-element cannot be accurately evaluated. Thus, the inventors have studied to form a dummy read-element having a size equal to that of a completed read-element or the desired read-element when the read-element to be actually used in a product is formed in the wafer so as to evaluate the characteristic of the read-element to be actually used by testing the dummy read-element.

Characteristic variation of the read-element must be tested in a heating state or a cooling state. Further, durability of the read-element in the heating state must be tested. In case of testing the read-element in the heating state or the cooling state, the test has been performed by placing a test sample in a constant-temperature tank. Therefore, by performing the heating test or the cooling test in the form of the wafer, heat or heat cycle is applied to not only the dummy read-element but also the read-element to be actually used, so the characteristic of the read-element to be actually used will be worsened.

### SUMMARY OF THE INVENTION

The present invention was conceived to solve the above described problems.

An object of the present invention is to provide a suitable method for testing a characteristic of a magnetic head in the form of a wafer, especially in a heating state and a cooling state.

Another object is to provide a suitable apparatus for performing the method of the present invention.

A further object is to provide a wafer to be used in said test.

To achieve the objects, the present invention has following constitutions.

Namely, a method for testing a characteristic of a magnetic head, in which a wafer including a dummy read-element to be tested having a size equal to that of a completed read-element, a product read-element to be actually used in the magnetic head and a heat conductive section being provided in the vicinity of the dummy read-element is tested as a test sample, comprises the steps of: applying an external magnetic field for the test to the test sample; bringing a heat conducting member into contact with the heat conductive section so as to heat or cool the dummy read-element via the heat conductive section; and testing an electromagnetic conversion characteristic of the dummy read-element in a heating state or a cooling state.

In the method, the dummy read-element may be formed in each of exposure areas of the wafer, and the heat conductive section may be formed for each of the dummy read-elements. With this method, characteristic variation of the product read-elements, variation of film-forming conditions, etc. in the entire wafer can be detected.

An apparatus for testing a characteristic of a magnetic head comprises: means for applying an external magnetic field for the test to a test sample, which is a wafer including a dummy read-element to be tested having a size equal to that of a completed read-element, a product read-element to be actually used in the magnetic head and a heat conductive section being provided in the vicinity of the dummy read-element; heating/cooling means for heating or cooling the dummy read-element by bringing a heat conducting member into contact with the heat conductive section so as to heat or cool the dummy read-element via the heat conductive section; and a testing unit for testing an electromagnetic conversion characteristic of the dummy read-element in a heating state or a cooling state. With this structure, the dummy read-element formed in the wafer can be effectively heated and cooled so as to test an electromagnetic conversion characteristic thereof.

In the apparatus, the heating/cooling means may have the heat conducting member equipped with a Peltier element. With this structure, the characteristic of the minute read-element can be accurately tested in the heating state or in the cooling state.

Further, a wafer for producing a magnetic head comprises: a dummy read-element to be tested having a size equal to that of a completed read-element; a product read-element to be actually used in the magnetic head; and a heat conductive section for heating or cooling the dummy read-element, the heat conductive section being provided in the vicinity of the dummy read-element. By using the wafer of the present invention, the characteristic of the dummy read-element can be tested in the state of being effectively heated or cooled.

In the wafer, the dummy read-element may be formed in each of exposure areas of the wafer, and the heat conductive section may be formed for each of the dummy read-elements. With this structure, characteristic variation of the product read-elements, variation of film-forming conditions, etc. in the entire wafer can be securely checked.

In the method and the apparatus of the present invention, the electromagnetic conversion characteristic of the dummy read-element, whose size is equal to that of the completed read-element and which is included in the wafer, is tested, so that product failure in the wafer, etc. can be checked. Especially, by testing the characteristic with heating or cooling the dummy read-element via the heat conductive section, the characteristic of the dummy read-element can be precisely tested so that the problem of product failure, etc. can be checked in the form of the wafer.

### BRIEF DESCRIPTION OF THE DRAWINGS

Embodiments of the present invention will now be described by way of examples and with reference to the accompanying drawings, in which:

FIGS. 1A and 1B are sectional views of a dummy read-element and a product read-element;

FIG. 2 is an explanation view showing an example of arranging read-elements in a wafer;

FIG. 3 is a schematic view of an apparatus for testing characteristics of the read-elements; and

FIGS. 4A-4C are explanation views showing a process of testing a characteristic of the read-element with bringing a heat conducting member into contact with a heat conductive section of the wafer.

### DETAILED DESCRIPTION OF THE EMBODIMENTS

Preferred embodiments of the present invention will now be described in detail with reference to the accompanying drawings.

### (Wafer for Producing Magnetic Head)

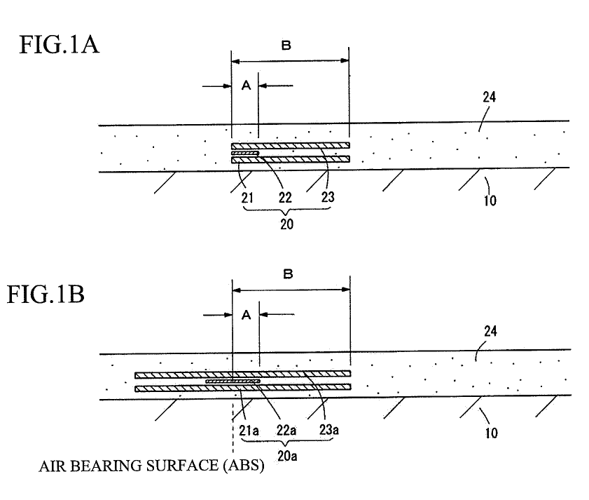

FIGS. 1A and 1B are sectional views of read-elements formed in a wafer substrate, which is composed of ALTIC (Al₂O₃-TiC), seen from a direction perpendicular to an air bearing surface (ABS).

A dummy read-element to be tested, which is formed in the wafer substrate 10, is shown in FIG. 1A; a product read-element to be actually used in the magnetic head, which is also formed in the wafer substrate 10, is shown in FIG. 1B. An electromagnetic conversion characteristic of the dummy read-element is tested in the form of the wafer.

In FIG. 1A, a dummy read-head 20 is formed by laminating a lower shielding layer 21, a dummy read-element 22 and an upper shielding layer 23 on the wafer substrate 10.

In FIG. 1B, a product read-head 20a is formed by laminating a lower shielding layer 21a, a product read-element 22a and an upper shielding layer 23a on the wafer substrate 10. Spaces between the lower shielding layer 21 or 21a, the read-element 22 or 22a and the upper shielding layer 23 or 23a are filled with an insulating material 24, e.g., alumina.

The lower shielding layers 21 and 21a and the upper shielding layers 23 and 23a are composed of a soft magnetic material, e.g., NiFe. Each of the read-elements 22 and 22a includes a pinned layer and a free layer constituted by magnetic layers and nonmagnetic layers. The shielding layers and the read-elements have known structures and the structures are not limited.

A difference between the dummy read-head 20 including the dummy read-element 22 and the product read-head 20a including the product read-element 22a is that sizes of the lower shielding layer 21, the dummy read-element 22 and the upper shielding layer 23 of the dummy read-head 20 are equal to those of a completed read-head having a desired read-head.

In FIG. 1A, the size of the read-element 22 in the height direction is A; the size of the lower shielding layer 21 and the upper shielding layer 24 in the height direction is B. In the completed read-head, end faces of a lower shielding layer, a read-element and an upper shielding layer are included in an ABS, so the end faces are located on a straight line.

The size A of the read-element 22 and the size B of the lower shielding layer 21 and the upper shielding layer 23 are shown in FIG. 1B for comparison. As shown in FIG. 1B, in the form of the wafer, the lower shielding layer 21a, the read-element 22a and the upper shielding layer 23a of the product read-head 20a are extended beyond the ABS. After a raw bar is cut from the wafer, sizes of the lower shielding layer 21a, the read-element 22a and the upper shielding layer 23a in the height direction are defined by abrading the raw bar, so that a product size can be defined.

In the method for testing characteristics of a magnetic head relating to the present invention, the dummy read-head 20 and the product read-head 20a are formed in the same wafer substrate 10. The dummy read-head 20 and the product read-head 20a may be formed by a known conventional method of producing a read-head. Namely, the read-heads are formed and arranged in a matrix, according to arrangement of sliders, in the wafer substrate 10. In the known method of producing the read-heads, a lower shielding layer, a read-element and an upper shielding layer are patterned and laminated in each of the read-heads, so the dummy read-heads 20 and the product read-heads 20a may be formed into respective planar patterns in the patterning step.

A method for producing the dummy read-element 20 is not limited to the patterning process. For example, the dummy read-element 20 may be formed by the steps of: forming a read-element in the wafer substrate 10 by a known process; forming a read-head; and trimming the read-head, by suitable means, e.g., ion milling, until the size of the read-element reaches the desired size of the completed read-element.

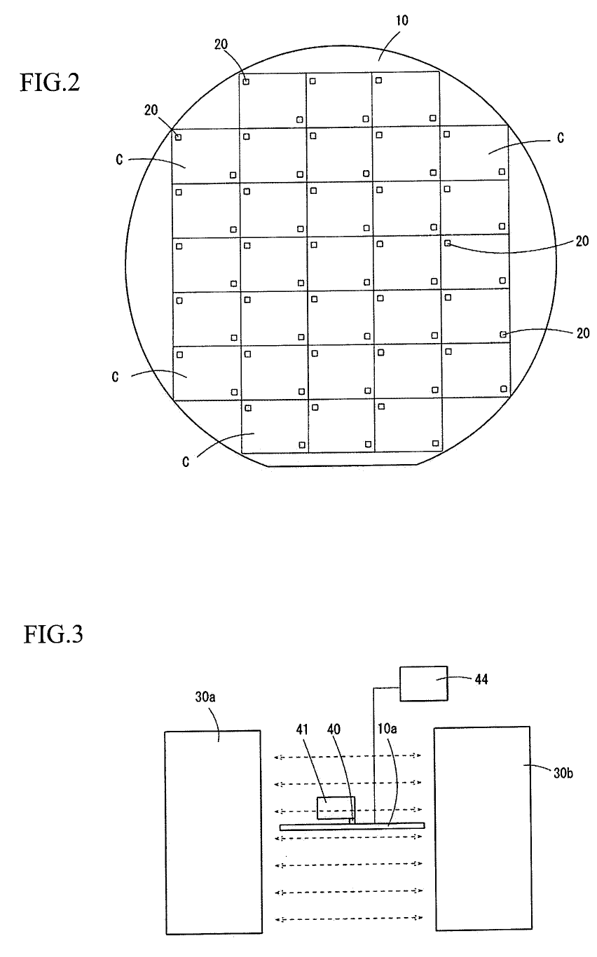

The dummy read-heads 20 are placed at suitable positions in the wafer substrate 10. An arrangement of the dummy read-heads 20 formed in the wafer substrate 10 is shown in FIG. 2. In FIG. 2, rectangular areas C are exposure areas, each of which is optically exposed by one exposing action. In the present embodiment, the dummy read-heads 20 are respectively placed at diagonal corners of each exposure area C.

In the step of forming the read-elements, magnetic layers are patterned and etching is performed. By performing these operations, characteristics of the read-elements will vary with respect to each exposure area C formed in the wafer substrate 10. Further, in case of forming a magnetic layer on the surface of the wafer substrate 10, a thickness of the wafer substrate 10 will be varied with locations. By dividing the planar surface of the wafer substrate 10 into a plurality of the exposure areas C and forming the read-elements in the exposure areas C, the variation of the characteristics of the read-elements in the planar area of the wafer substrate 10 can be accurately evaluated.

### (Method for Testing Characteristic of Magnetic Head)

A method for testing read-elements in a wafer 10a, which is a test sample and in which the dummy read-heads 20 and the product read-heads 20a are formed, will be explained with reference to FIG. 3.

The characteristic test of the read-elements is performed by placing the wafer 10a at a mid position between a pair of electromagnets 30a and 30b faced each other and applying an external magnetic field to the wafer 10a with bringing a heat conducting member 40 into contact with the wafer 10a so as to heat or cool the wafer 10a.

In the present embodiment, the electromagnets 30a and 30b act as the means for applying the external magnetic field to the test sample. The applying means is capable of suitably controlling a direction and a largeness of the magnetic field. The heat conducting member 40 constitutes the heating/cooling means for heating or cooling the dummy read-elements by bringing the heat conducting member 40 into contact with the wafer 10a so as to heat or cool the dummy read-elements. A testing unit 44 for measuring output signals of the dummy read-elements, which will be measured when the external magnetic field is applied to the test sample, is provided.

The heat conducting member 40, which constitutes the heating/cooling means, may include a heater for heating the dummy read-element or a Peltier element for heating the dummy read-element by heat conduction from a heat source. In the present embodiment, the Peltier element is used in the heat conducting member 40. In FIG. 3, the Peltier element is used in the heat conducting member 40, and a heat sink 41 for heat radiation is provided thereto.

In the present embodiment, a characteristic of each of the dummy read-elements is tested with bringing the heat conducting member 40 into contact with the wafer 10a so as to effectively heat or cool each of the dummy read-elements and accurately test the characteristic of each of the dummy read-elements in a heating state or a cooling state.

In the present embodiment, heat conductive sections 50, which are composed of a material having superior heat conductivity, are formed in the wafer substrate 10 and respectively located close to the dummy read-elements 20 formed in the wafer substrate 10.

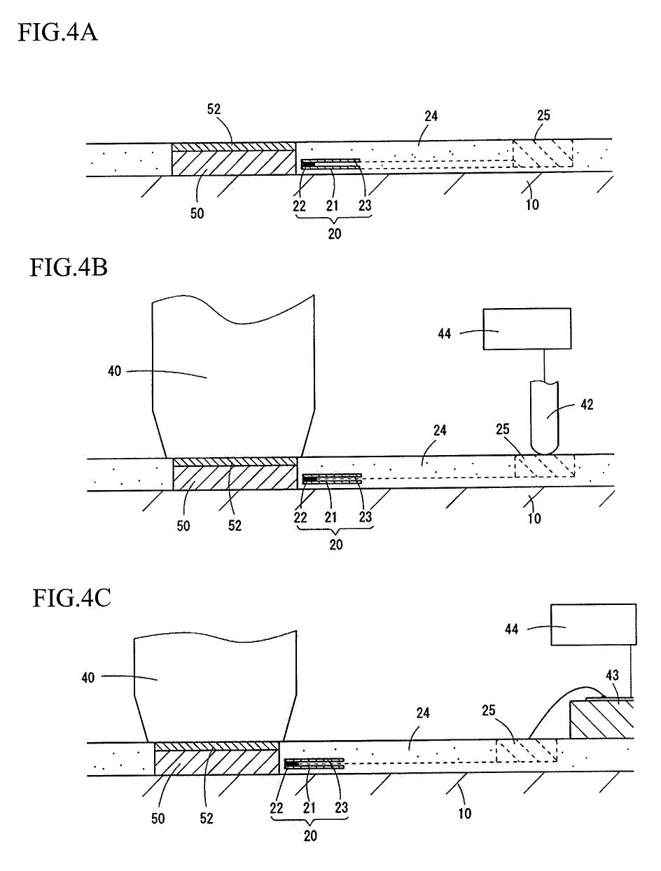

A partially enlarged view of the wafer substrate including the dummy read-head 20 is shown in FIG. 4A. The heat conductive section 50 is composed of a metal, e.g., copper, whose heat conductivity is higher than an insulating material. Films of the heat conductive sections 50 may be formed on the surface of the wafer substrate 10 by plating or sputtering. Since the dummy read-heads 20 are located at prescribed positions in the wafer substrate 10, the heat conductive sections 50 are respectively provided in the vicinities of the dummy read-heads 20. To effectively conductive heat from the heat conductive sections 50 to the dummy read-heads 20, the heat conductive sections 50 are located possibly close to the dummy read-heads 20 respectively. Note that, in case that the heat conductive sections 50 are composed of an electrically conductive material, the heat conductive sections 50 must be separated from the dummy read-heads 20 so as to prevent short circuit therebetween.

The heat conductive sections 50 are formed so as to effectively heat and cool the dummy read-elements 22, but their configurations are not limited. The dummy read-elements 22 are used for the characteristic tests only but not used in products, so positions, configurations, etc. of the heat conductive sections 50 may be optionally designed.

In the present embodiment, protection layers 52, which have corrosion resistance and are composed of, for example, gold, are respectively formed on the surfaces of the heat conductive sections 50. In case of performing heat cycle tests at high temperature, the protection layers 52 prevent the heat conductive sections 50 from being corroded.

To test characteristics of the dummy read-elements 22, the heat conducting member 40 is brought into contact with the dummy read-elements 22 in order. If the heat conductive sections 50 are corroded while performing the tests, the heat conducting member 40 cannot be securely brought into contact with the heat conductive sections 50 and the heat cannot be conducted from the heat conducting member 40 to the heat conductive sections 50. By forming the protection layers 52, the heat conducting member 40 can be securely brought into thermal-contact with the heat conductive sections 50, so that the characteristic tests of the dummy read-elements 22 can be securely performed in the heating state or the cooling state.

A partially enlarged view of the wafer substrate, wherein the heat conducting member 40 contacts the heat conductive section 50 and the dummy read-element 22 is tested, is shown in FIG. 4B.

A contact face of the heat conducting member 40, which contacts the heat conductive section 50, is a flat face and capable of covering the entire surface of the heat conductive section 50. By bringing the contact face of the heat conducting member 40 into contact with the entire surface of the protection layer 52, the heat can be effectively conducted from the heat conducting member 40 to the heat conductive section 50.

The dummy read-element 22 is connected to a test terminal 25 for applying electricity, and a probe 42 of the testing unit 44 is brought into contact with the test terminal 25. The external magnetic field is applied to the wafer 10a, and an electromagnetic conversion characteristic of the dummy read-element 22 can be tested by measuring output signals of the dummy read-element 22 with the testing unit 44.

In the present embodiment, the dummy read-elements 22a are provided in each of the exposure areas C in the wafer 10a, so characteristic variations of the read-elements in the wafer 10a can be known, and good elements and bad elements therein can be checked.

In the present embodiment, the heat conductive sections 50, which have high heat conductivity, are respectively provided close to the dummy read-element 22, and the dummy read-elements 22 are heated or cooled via the heat conductive sections 50. Therefore, characteristics of the dummy read-elements 22 can be tested with effectively heating or cooling the dummy read-elements 22. In case of the conventional method using the constant-temperature tank, the entire wafer is heated or cooled, so the read-elements cannot be locally heated and cooled. Therefore, each of the read-elements cannot be sufficiently heated or cooled. On the other hand, in the present embodiment, only the dummy read-elements 22 can be intensively heated or cooled, so that characteristics of the dummy read-elements 22 can be accurately tested in the heating state or the cooling state.

By locally heating or cooling the dummy read-elements 22, the characteristic tests can be performed without thermally influencing the product read-elements 22a. Namely, the characteristic tests can be performed without badly influencing the product read-elements 22a.

In case of performing the characteristic tests with heating or cooling the dummy read-elements 22 by using the heat conducting member 40, the dummy read-elements 22 may be merely heated or cooled, and heating or cooling heat cycles may be applied to the dummy read-elements 22. Further, the dummy read-elements 22 may be heated to high temperature so as to perform accelerated heat tests. In any cases, overheating or overcooling the product read heads 20a, can be prevented by heating or cooling the dummy read-elements 22.

Note that, the temperatures for heating and cooling the dummy read-elements 22 can be optionally determined. For example, the heating temperature is 150° C., and the cooling temperature is −15° C.

In FIG. 4C, the test terminal 25 and a substrate 43 to be tested are connected by wire bonding instead of bringing the probe 42 into contact with the test terminal 25. In some cases of performing the heat cycle tests or the accelerated heat tests with using the probe 42, the testing unit 44 and the test terminal 25 cannot be sufficiently connected. In these cases, the test substrate 43 is securely connected to the test terminal 25 by wire bonding as shown in FIG. 4C, so that the highly reliable tests can be performed.

In the present embodiment, the characteristic tests of the dummy read-elements 22 are performed in the form of the wafer substrate 10, in which the dummy read-elements 22 and the product read-elements 22a have been formed. By testing the dummy read-elements 22 whose sizes are equal to that of the completed read-element or the desired read-element, characteristics of the product read-elements 22a can be accurately known in the form of the wafer substrate 10. Since characteristic variation of the read-elements can be known and bad elements can be checked in the form of the wafer substrate, the test results can be rapidly fed back to a prior production step before progressing the production steps.

If the characteristic tests of the read-elements are performed after forming sliders and the test results are fed back, the test results include problematical points occurred in the steps of not only forming the read-elements in the wafer substrate but also processing the sliders. Therefore, it is difficult to extract the problematical points occurred in only the step of forming the read-elements in the wafer substrate and feed back the extracted problematical points. On the other hand, in the present embodiment, the tests are performed when the dummy read-elements are formed in the wafer substrate, so that the test results can be fed back as the problematical points occurred in only the step of forming the dummy read-elements in the wafer substrate.

Further, in the present embodiment, characteristics of the dummy read-elements 22 can be easily evaluated in the heating state or the cooling state.

Note that, in the above described embodiment, characteristics of the dummy read-elements are tested in the form of the wafer substrate 10. In another case, characteristics of dummy read-elements may be tested in the form of the wafer substrate 10 in which the dummy read-elements and write-elements are formed. In this case too, the heat conductive sections 50 are formed in the wafer substrate 10a, so that the dummy read-elements 22 can be tested with intensively heating or cooling them. The write-element, in which magnetic layers and nonmagnetic layers are laminated, is formed on each of the dummy read-elements. In case of testing characteristics of the dummy read-elements after forming the write-elements, the heat conductive sections 50 are exposed in the surface of the wafer substrate 10a.

In case of forming the write-elements under the dummy read-elements, the heat conductive sections 50 are exposed in the surface of the wafer substrate 10a in the step of forming the read-elements.

In the above described embodiment, the sizes of the dummy read-elements are previously made equal to that of the desired read-element of the completed magnetic head, and then characteristics of the dummy read-elements are tested.

Further, in case that configurations of the dummy read-elements are similar to those of the product read-elements and certain level of characteristics of the dummy read-elements can be evaluated, the tests can be performed even if the sizes of the dummy read-elements are not equal to that of the completed read-element. In this case too, the heat conductive sections 50 are provided close to the dummy read-elements so as to locally heat or cool the dummy read-elements.

The invention may be embodied in other specific forms without departing from the spirit of essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. A method for testing a characteristic of a magnetic head, in which a wafer including a dummy read-element to be tested having a size equal to that of a completed read-element, a product read-element to be actually used in the magnetic head and a heat conductive section being provided in the vicinity of the dummy read-element is tested as a test sample, comprising the steps of:
applying an external magnetic field for the test to the test sample;
bringing a heat conducting member into contact with the heat conductive section so as to heat or cool the dummy read-element via the heat conductive section; and
testing an electromagnetic conversion characteristic of the dummy read-element in a heating state or a cooling state.

2. The method according to claim 1,
wherein the dummy read-element is formed in each of exposure areas of the wafer, and
the heat conductive section is formed for each of the dummy read-elements.

3. An apparatus for testing a characteristic of a magnetic head,
comprising:
means for applying an external magnetic field for the test to a test sample, which is a wafer including a dummy read-element to be tested having a size equal to that of a completed read-element, a product read-element to be actually used in the magnetic head and a heat conductive section being provided in the vicinity of the dummy read-element;
heating/cooling means for heating or cooling the dummy read-element by bringing a heat conducting member into contact with the heat conductive section so as to heat or cool the dummy read-element via the heat conductive section; and
a testing unit for testing an electromagnetic conversion characteristic of the dummy read-element in a heating state or a cooling state.

4. The apparatus according to claim 3,
wherein the heating/cooling means has the heat conducting member equipped with a Peltier element.

5. A wafer for producing a magnetic head,
comprising:
a dummy read-element to be tested having a size equal to that of a completed read-element;
a product read-element to be actually used in the magnetic head; and
a heat conductive section for heating or cooling the dummy read-element, the heat conductive section being provided in the vicinity of the dummy read-element.

6. The wafer according to claim 5,
wherein the dummy read-element is formed in each of exposure areas of the wafer, and
the heat conductive section is formed for each of the dummy read-elements.
